(19) United States
(12) Patent Application Publication
(10) Pub. No.: US 2025/0303579 A1
(43) Pub. Date: Oct. 2, 2025

(54) END-EFFECTOR AND METHOD FOR HANDLING A SUBSTRATE

(71) Applicant: ASML Netherlands B.V., Veldhoven (NL)

(72) Inventors: Gijs KRAMER, Nijmegen (NL); Stephanus Cornelis Leonardus VAN DE VEN, Veldhoven (NL); René BOERHOF, Vlijmen (NL)

(73) Assignee: ASML Netherlands B.V., Veldhoven (NL)

(21) Appl. No.: 18/851,144

(22) PCT Filed: Mar. 13, 2023
(86) PCT No.: PCT/EP2023/056327

§ 371 Date: Sep. 26, 2024

(30) Foreign Application Priority Data
Mar. 31, 2022 (EP) 22165835.4

(51) Int. Cl. B25J 11/00; B25J 15/02; B25J 19/00; H01L 21/687

(52) U.S. Cl. CPC B25J 11/0095; B25J 15/024; B25J 19/0016; H01L 21/68707

(57) ABSTRACT

An end-effector is disclosed for handling a substrate, comprising: a base; a clamping body comprising an actuator configured to switch between a first position, wherein the substrate is fixed in position with respect to the clamping body, and a second position, wherein the substrate is released; a guidance mechanism connecting the clamping body to the base while allowing freedom of movement of the clamping body relative to the base within a predetermined range of motion; and a fixation mechanism for switching a connection between the clamping body and the base between a fixed position, wherein the clamping body is fixated relative to the base, and a free position, wherein the clamping body can move relative to the base.

### CROSS-REFERENCE TO RELATED APPLICATION

The application claims priority of EP application 22165835.4 which was filed on 31 Mar., 2022 and which is incorporated herein in its entirety by reference.

### FIELD

The present invention relates to an end-effector and a method for handling a substrate. The substrate may be, for instance, a wafer, a mask, or a reticle. The substrate may be intended for use in a lithographic apparatus and/or a lithographic process.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer).

As semiconductor manufacturing processes continue to advance, the dimensions of circuit elements have continually been reduced while the amount of functional elements, such as transistors, per device has been steadily increasing over decades, following a trend commonly referred to as ‘Moore's law’. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm. A lithographic apparatus, which uses extreme ultraviolet (EUV) radiation, having a wavelength within a range of 4 nm to 20 nm, for example 6.7 nm or 13.5 nm, may be used to form smaller features on a substrate than a lithographic apparatus which uses, for example, radiation with a wavelength of 193 nm.

There are various end-effectors for handling wafers. There are end-effectors that clamp at the underside of a wafer via e.g. vacuum, gravity or electrostatic interactions.

KR100777201B1 discloses an end-effector having grippers (30, 40) on two different structures (10, 20) which can be movable relative to each other, for example by pneumatics, to control a gripping action.

US20090175705A1 describes a substrate transfer apparatus capable of supporting a wafer from above. The grip mechanism has a fixed support part (28a) and a movable support part (28b) which can be pneumatically controlled.

The prior art end-effectors described above have a fixed position relative to the robot that manoeuvres them. As a consequence, very accurate positioning of the end-effector relative to the wafer is required. Without precise alignment, the wafer may be pushed against edges of the gripper, which can damage the wafer. Additional actuators may increase positioning precision but add cost, volume and complexity. They also give rise to heat dissipation which can degrade the accuracy of subsequent processing of wafers.

The present disclosure aims to provide an improved end-effector, obviating one or more of the disadvantages of the prior art end-effectors.

### SUMMARY

The disclosure provides an end-effector for handling a substrate, comprising:
a base;
a clamping body comprising an actuator configured to switch between a first position, wherein the substrate is fixed in position with respect to the clamping body, and a second position, wherein the substrate is released;
a guidance mechanism connecting the clamping body to the base while allowing freedom of movement of the clamping body relative to the base within a predetermined range of motion; and
a fixation mechanism for switching a connection between the clamping body and the base between a fixed position, wherein the clamping body is fixated relative to the base, and a free position, wherein the clamping body can move relative to the base.

In an embodiment, the clamping body comprises at least one fixed finger and at least one actuating finger being provided with the actuator, wherein in the first position the substrate is fixed in position between ends of the at least one fixed finger and the actuator of the at least one actuating finger.

In an embodiment, the guidance mechanism comprises at least one spring element, each spring element having one end connected to the base and an opposite end connected to the clamping body.

In an embodiment, the at least one spring element comprises a leaf spring, or a bent piece of flexible material, such as spring steel or a similar material.

In an embodiment, the ends of the at least one spring element are connected to the base and to the clamping body by one or more of an adhesive, welding, or soldering.

In an embodiment, the at least one spring element has a shape allowing relative motion of its opposite ends in the horizontal plane (x, y) while preventing or at least limiting movement in the vertical direction (z).

In an embodiment, the predetermined range of motion allowed by the guidance mechanism includes lateral movement in the horizontal plane of +/−500 μm, for instance about +/−250 μm, for instance about +/−200 μm, for instance about +/−150 μm, for instance about +/−100 μm, for instance about +/−50 μm, for instance about +/−20 μm, for instance about +/−10 μm.

In an embodiment, the predetermined range of motion allowed by the guidance mechanism includes rotation θ, wherein θ is in a range of +/−5 degrees, for instance +/−4 degrees, for instance +/−3 degrees, for instance +/−2 degrees, for instance +/−1 degree, for instance +/−0.5 degrees, for instance +/−0.4 degrees, for instance +/−0.3 degrees, for instance +/−0.2 degrees, for instance +/−0.1 degree.

In an embodiment, the guidance mechanism is adapted to move the clamping body to a reference position with respect to the base when the fixation mechanism is in the free position.

In an embodiment, the fixation mechanism comprises at least one vacuum line. The at least one vacuum line may control the actuator. The at least one vacuum line may control the fixation mechanism. The at least one vacuum line may comprise a first section included in the base, the first section being connected to a vacuum bridge having one or more openings connecting the first section in the base to a corresponding vacuum line section in the clamping body, the vacuum line section in the clamping body being connected to the actuator.

In an embodiment, the vacuum line section in the clamping body is provided with a check valve and/or a flow restrictor.

In an embodiment, the actuator comprises a spring for pre-tensioning a gripper, the spring pushing the gripper outward in a position allowing engagement with an edge of the substrate.

According to another aspect, the disclosure provides a lithographic apparatus comprising the end-effector as described above.

According to yet another aspect, the disclosure provides a method of using an end-effector for handling a substrate,
the end-effector comprising:
a base;
   a clamping body comprising an actuator configured to switch between a first position, wherein the substrate is fixed in position with respect to the clamping body, and a second position, wherein the substrate is released;
a guidance mechanism connecting the clamping body to the base while allowing freedom of movement of the clamping body relative to the base within a predetermined range of motion; and
a fixation mechanism for switching a connection between the clamping body and the base between a fixed position, wherein the clamping body is fixated relative to the base, and a free position, wherein the clamping body can move relative to the base,
the method comprising the steps of:
moving the clamping body in lateral direction covering a substrate;
lowering the clamping body onto the substrate;
switching the fixation mechanism to the free position;
switching the actuator to the first position;
switching the fixation mechanism to the fixed position;
lifting the clamping body and the substrate and moving the clamping body to another location;
switching the actuator to the second position;
lifting the clamping body without the substrate.

In an embodiment, the step of switching the fixation mechanism to the fixed position includes decreasing a pressure in a first vacuum line below a first threshold Pₜₕᵣ₁.

In an embodiment, the step of switching the fixation mechanism to the free position includes increasing a pressure in the first vacuum line to exceed a second threshold Pₜₕᵣ₂.

In an embodiment, the step of switching the actuator to the second position includes decreasing a pressure in a second vacuum line to below a third threshold Pₜₕᵣ₃ and/or wherein the step of switching the actuator to the first position includes increasing a pressure in the second vacuum line to exceed a fourth threshold Pₜₕᵣ₄.

In an embodiment, the method comprises the step of projecting a patterned beam of radiation onto the substrate.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus;

FIG. 2 depicts a schematic side view of an embodiment of an end-effector of the disclosure;

FIG. 3A depicts a schematic top view of the end-effector of FIG. 2 along line III-III;

FIG. 3B depicts a schematic perspective view of an embodiment of the end-effector;

FIG. 3C depicts a schematic perspective view of another embodiment of the end-effector;

FIG. 4 depicts a schematic side view of another embodiment of an end-effector of the disclosure;

FIGS. 5 to 12 depict a schematic side view of an embodiment of an end-effector during respective steps of an embodiment of a method of the disclosure; and

FIG. 13 shows an exemplary diagram of a pressure P in a vacuum line (vertical axis) versus time (horizontal axis), allowing to switch the end-effector of the disclosure between respective positions.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

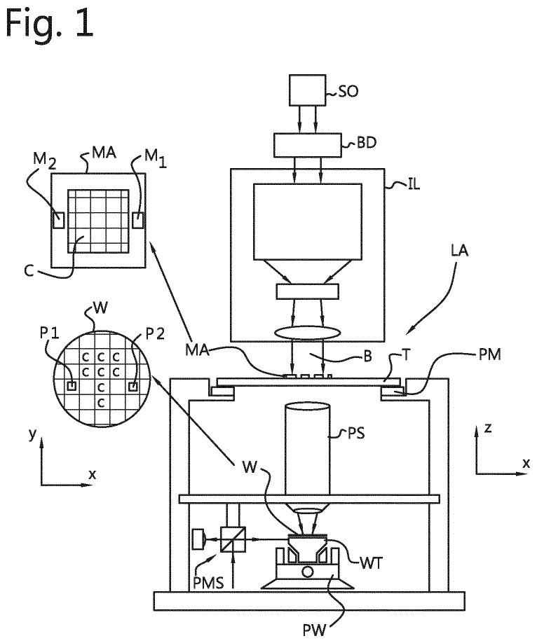

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) T constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W-which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support T, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system PMS, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

To clarify the invention, a Cartesian coordinate system is used. The Cartesian coordinate system has three axes, i.e., an x-axis, a y-axis and a z-axis. Each of the three axes is orthogonal to the other two axes. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

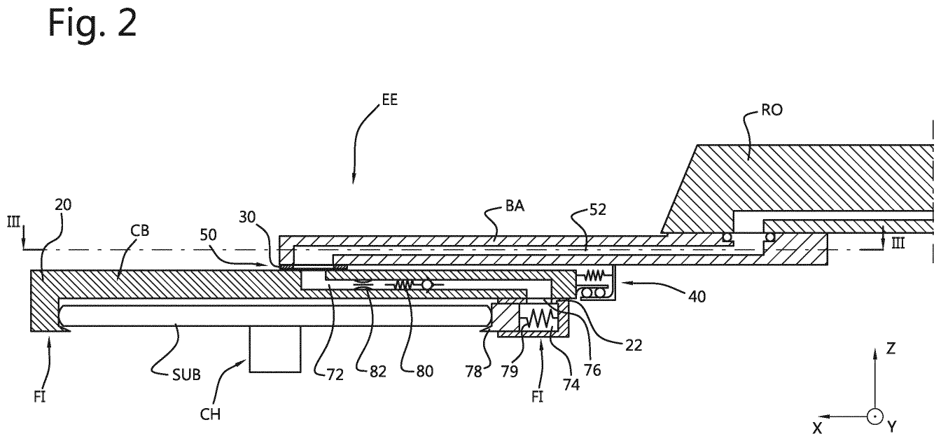

Generally referring to FIGS. 2 to 4, a new end-effector EE is provided. The end-effector may comprise a base BA. The base BA may be fixed to, or fixedly attached to, a robot RO. The end-effector EE may comprise a clamping body CB. The body CB may be a ‘floating’ clamping body that is free of the robot RO. Free herein means, for instance, that the clamping body CB can move within a certain range with respect to the base and/or the robot.

The clamping body may be provided with one or more, typically a number of, fingers FI for holding and releasing a substrate SUB. The substrate may be, for instance, a wafer W, a reticle or a mask MA. At least one finger 20 of the one or more fingers FI may be fixed. The one or more fixed fingers 20 have an end to align to the edge of the substrate SUB (left side in FIG. 2). At least one other finger may be an actuating finger 22 that is moveable, or has a section that is moveable, with respect to the clamping body CB. The actuating finger 22 allows to hold the substrate SUB in position, for instance by clamping the substrate between ends of the respective fingers, and to subsequently release the substrate. The end-effector EE can, for instance, move the substrate SUB between one location and another. For instance, the end-effector can move the substrate to a chuck or similar holding structure CH which may typically be provided on top of the wafer table WT (see FIG. 1) from another location, and subsequently remove the substrate from the chuck. Said other location may be, but is not limited to, another wafer table, a storage facility, or a container for holding wafers in between respective lithography steps.

The base BA may be reversibly fixable to the clamping body CB via an interface 30. The interface may be, but not limited to, pneumatic. The interface 30 may instead be, for instance, mechanical or electro-magnetic. When the clamping body CB is fixed to the base BA, the end-effector (by virtue of its connection to, for instance, a handler robot) is configured to align the fixed finger(s) 20 of the clamping body to the wafer, which avoids possible damage to wafer.

The interface 30 gives rise to an actuation mechanism between the base BA and the clamping body CB. The actuation mechanism is configured to actuate the at least one actuating finger 22 of the clamping body, to enable clamping and unclamping of the substrate SUB. The end-effector may include a guidance mechanism 40 providing freedom of movement for the clamping body CB with respect to the base BA within a predetermined range.

The guidance mechanism may include, for instance, one or more springs or spring elements 42, 44, 46 connecting the clamping body to the base BA. The spring elements 42-46 may for example be leaf springs and/or may include a bent piece of flexible material, such as spring steel or a similar material. Opposite ends of the spring elements are connected to the base and to the clamping body respectively. The ends of the spring elements can be connected to the base and clamping body, for instance, by an adhesive, by welding, or by soldering. The spring elements 42-46 may have a shape allowing relative motion of its opposite ends in the horizontal plane (x, y) while preventing or at least limiting movement in the vertical direction (z). The guidance mechanism 40 may allow the clamping body to move in, for instance, up to three degrees of freedom with respect to the base BA and/or the robot RO. Said degrees of freedom may include, for instance, one or more of lateral translation in the horizontal plane (tₓ, t_{y}) and rotation in the horizontal plane (r_{z}).

The movement of the clamping body with respect to the base BA allows the clamping body to adapt to the position of the substrate SUB, in addition to positioning controlled by the robot RO. In practice, during a lithography process the substrate may be positioned slightly off centre (eccentric) on the chuck CH. Although the lithography process itself can adapt to this eccentricity within a certain range, it is important to maintain the same relative eccentricity for the same wafer for subsequent steps in the lithographic process. After all, for every step in the process, the lithographic apparatus may need to identify the markers (see FIG. 1, for example markers P1, P2 for the wafer W, and for example markers M1, M2 for the mask MA) before illumination, to allow the required precision for processing respective layers on the wafer. To maintain a throughput above a threshold suitable for commercial application, it is important that the apparatus LA can locate the markers in a predetermined time period that is sufficiently fast. Maintaining the same position of substrates relative to the chuck between respective lithography steps ensures that the markers maintain the same relative position as well, so that the apparatus LA can readily locate the markers. The guidance mechanism 40 provides an additional means to precisely position the clamping body with respect to the substrate, in addition to movements controlled by the robot RO. In practice, the guidance mechanism provides a means to improve the level of accuracy of movement of the clamping body over the accuracy of movement of the robot. Herein, the method and system of the disclosure obviate bulky add-ons and actuators, and allow the use of a relatively simple and modestly priced robot RO, while still providing a relatively good accuracy. After clamping the clamping body to the substrate, the position of the clamping body and the clamped substrate can be fixated with respect to the base BA, allowing to maintain the exact location of the substrate between respective locations and between respective steps of the lithographic process.

In a practical embodiment, the predetermined range of motion allowed by the guidance mechanism 40 may be, for instance, about +/−5 mm, +/−4 mm, +/−3 mm, 2.5 mm, +/−2 mm, +/−1.5 mm, +/−1 mm, +/−500 μm, +/−500 μm, +/−250 μm, +/−200 μm, +/−150 μm, +/−100 μm, +/−50 μm, +/−20 μm+/−10 μm for lateral movement in the horizontal plane (translation in the x-direction and/or y-direction, see FIG. 2).

One may wish to express rotation r allowed by the guidance mechanism as a rotation vector, or Euler vector, an un-normalized three-dimensional vector: r=θê. Herein, the direction of the axis of rotation is determined by ê=[eₓ, e_{y}, e_{z}]. In a practical embodiment, the guidance mechanism ensures that e_{z}>>eₓ, e_{y}. As a result, r is substantially equal to r_{z}, i.e. a rotation around the vertical axis. The length of the rotation vector r is determined by the angle of rotation θ. In a practical embodiment, the guidance mechanism 40 may allow θ in a range of about +/−1 degree, +/−2 degrees, +/−3 degrees, +/−4 degrees, +/−5 degrees, +/−6 degrees, +/−7 degrees, +/−8 degrees, +/−9 degrees, +/−10 degrees, or more.

The end-effector may include a compliance mechanism. The compliance mechanism has a function to move the clamping body CB to a reference position with respect to the base BA. In the embodiment as described above, the guidance mechanism includes spring elements 42, 44, 46. Herein, the spring elements function as compliance mechanism. Thus, for example, the compliance mechanism and the guidance mechanism can be integrated, i.e. the spring elements function both as compliance mechanism and as guidance mechanism.

The end-effector EE may include a fixation mechanism 50. The fixation mechanism can be integrated in the interface 30. The fixation mechanism is adapted to ensure that the clamping body CB can switch between a free position or moveable position, wherein the body CB can move with a certain range with respect to the base BA, and a fixed position, wherein the body CB is fixated with respect to the base BA. The fixation mechanism may also allow the clamping body to have freedom to clamp, i.e. to control the actuator 74.

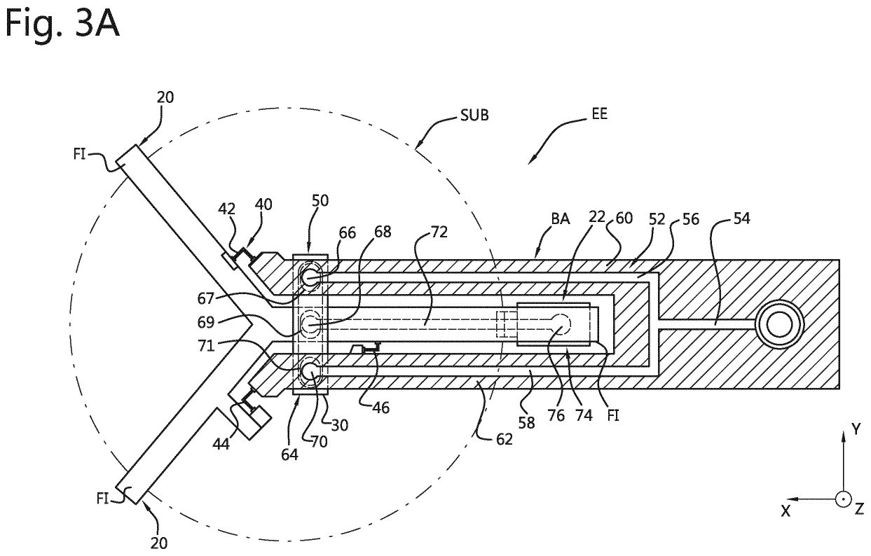

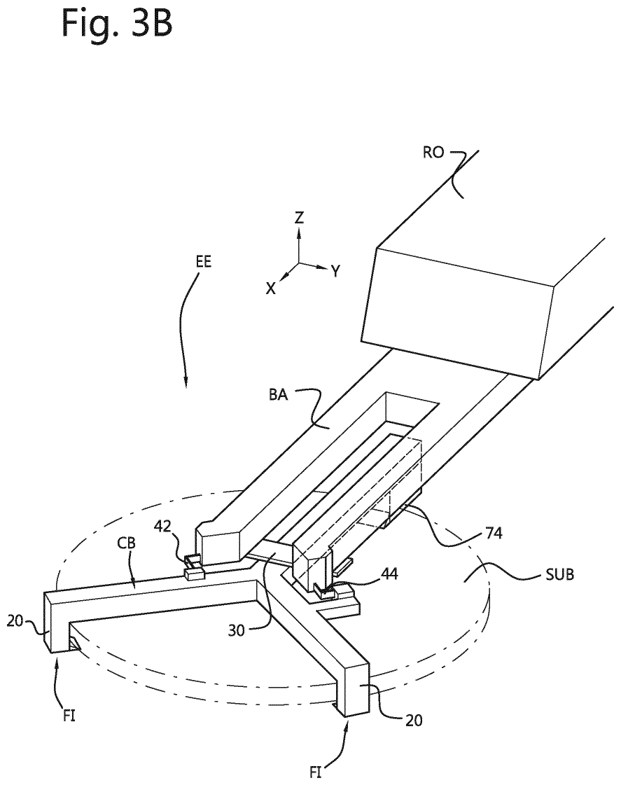

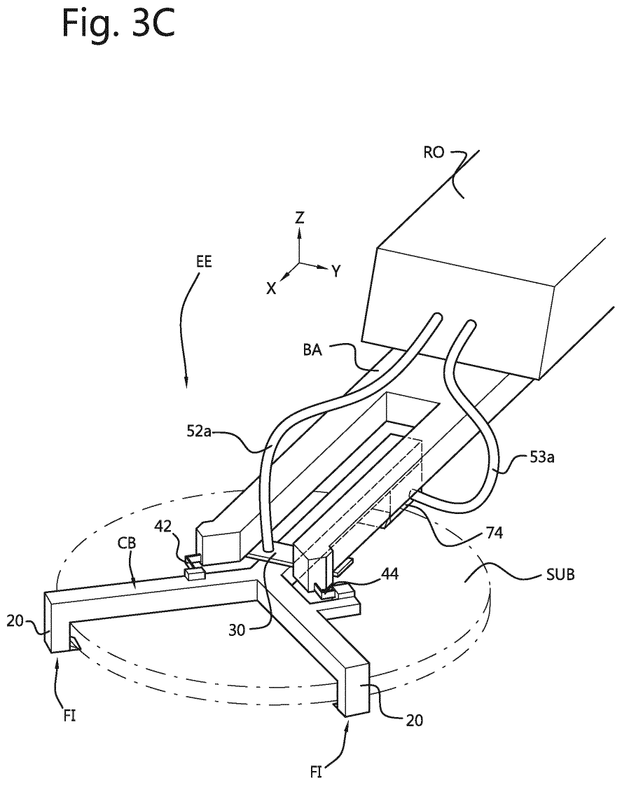

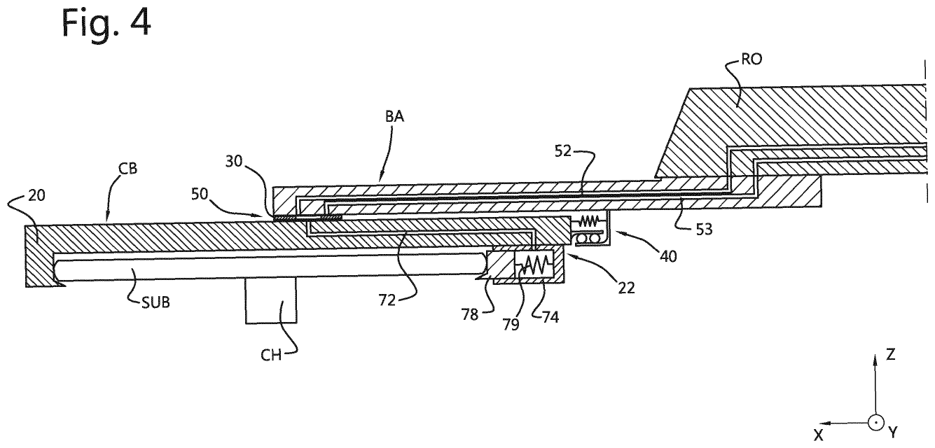

In an embodiment, the end-effector EE may comprise, for instance, one or more vacuum lines for controlling the fixation mechanism 50 and/or the actuator 74. The at least one vacuum line may comprise a first vacuum line 52 and/or a second vacuum line 53. The second vacuum line is described in more detail below with respect to FIG. 4. The first vacuum line 52 may comprise a first section 54 included in the base BA. As shown in FIG. 3A, the base itself may have a forked structure, comprising a number of, for instance two, fingers 60, 62. The first section 54 may split into two second sections 56, 58 included in the respective base fingers 60, 62. The second vacuum line sections 56, 58 can be connected to a vacuum bridge or vacuum connector 64. The vacuum connector is included in the interface 30. The vacuum bridge may have one or more openings 66, 68, 70 allowing to connect the one or more vacuum line sections 56, 58 in the base BA to a corresponding vacuum line section 72 in the clamping body CB. One or more of the openings 66, 68, 70 may be provided with suitable vacuum seals or gaskets 67, 69, 71. Said seals may be O-rings made of a suitable material. The material may be rubber or a specialty polymer suitable as a seal for (high) vacuum environments.

A pressure in the line 52 may control whether the clamping body is free to move with respect to the base BA, or is fixed to the base. The pressure in line 52 can be controlled using a suitable pump and controller (not shown), which may be included in or connected to the robot RO. With general reference to FIG. 13, as an example, if the pressure in line 52 drops below a predetermined first threshold Pₜₕᵣ₁, the relative vacuum in the line 52 fixates the clamping body with respect to the base. For instance if the pressure in the line 52 exceeds a predetermined second threshold Pₜₕᵣ₂, the clamping body is released from the base and, as described herein, is free to move with respect to the base. The first and second pressure thresholds may be substantially the same, or may slightly differ.

The body vacuum line 72 may connect the opening 68 of the vacuum bridge to an actuator 74 via an opening 76. The actuator 74 may be a pneumatic actuator. The actuator 74 can move between a first position, e.g. an open position, wherein the actuator is disengaged from the substrate SUB, and a second position, e.g. a closed position, wherein an edge or gripper 78 of the actuator (see FIG. 2) engages a side of the substrate.

In a practical embodiment, the actuator may comprise a spring 79. The spring 79 can pre-tension the gripper 78, pushing the gripper outward, in a position allowing engagement with the edge of the substrate. The spring 79 has a certain spring constant k. The spring force formula is expressed through the equation F=−kx. Where F is the force applied, k is the spring constant and measures how stiff and strong the spring is proportionally, and x is the distance the spring is stretched or compressed away from its equilibrium or rest position. The force may be expressed in Newton per meter (N/m). The minus sign shows that this force is in the opposite direction of the force that is stretching or compressing the spring. The spring may have a spring force in the opposite direction of compression. As a pressure in the line 72 drops, the edge 78 of the actuator 74 will be pulled inward, compressing the spring 79.

With general reference to FIG. 13 for a practical example, when the pressure drops below a certain value, for instance below a third threshold Pₜₕᵣ₃, the gripper 78 may release the edge of the substrate. The third threshold Pₜₕᵣ₃ may be between pressures P₂ and P₃ (described in more detail herein below).

The body vacuum line 72 may be provided with a valve 80 and/or a flow restrictor 82. The valve and flow restrictor may allow or enable two-level pressure switching for separate actions, such as fixation of the clamping body CB with respect to the base BA (via the interface 30) and clamping or unclamping of the substrate (via the actuator 74).

The valve 80 may be a check valve. A check valve may also be referred to as non-return valve, reflux valve, retention valve, foot valve, or one-way valve. A check valve is a valve that normally allows fluid (liquid or gas) to flow through it in only one direction. In the embodiment of FIG. 2, the check valve 80 may allow flow from the actuator 74 to the base BA. This allows a vacuum in the line 52 to remove gas from the actuator. The vacuum can be continually activated using a pump connected upstream to the line 52. In practice, the actuator 74 will typically always leak at least a little, for instance via sides of the gripper edge 78. The latter allows to deactivate the valve 80, typically including a delay depending on the rate of gas leakage. The valve 80 can be deactivated, for instance, by ending the actively applied vacuum via the vacuum line 72, 52. With reference to FIG. 13, applying a pressure in the order of P₂ in the lines 52, 72 may allow to deactivate the actuator 74 while keeping the fixation mechanism 50 in the interface 30 activated, i.e. in the fixed position. Deactivation of the fixation mechanism 50 while the actuator 74 is still activated (for a while, depending on the rate of gas leak in the actuator) and thus clamping and holding the substrate is also possible. The latter can be done by, for instance, switching the supply of gas to near the reference pressure (for example, a pressure in line 52 of about 1 atm or P₃ as indicated in FIG. 13), while the throttling device 82 slows the change in pressure on the upstream side of the valve 80.

FIG. 4 shows an alternative embodiment of the end-effector EE. Instead of the valve 80 and throttling device 82, the base BA may be provided with two or more pneumatic lines or vacuum lines 52, 53. Herein, line 52 may be connected to the actuator 74 via a corresponding vacuum line section 72 in the clamping body, as described above. The second pneumatic line or second vacuum line 53 may be connected to and can control the fixation mechanism 50. Herein, a vacuum in the line 53 may lock or fixate the clamping body with respect to the base. A higher pressure, for instance atmospheric pressure, in the line 53 may allow the body CB to move with respect to the base within constraints as set by the guidance mechanism 40.

FIG. 3C shows another embodiment, wherein the vacuum lines are provided as tubes 52a, 53b. Herein, the first tube 53a connects a first vacuum device, such as a pump, in or connected to the robot RO to the actuator 74. The second tube 52a connects a second vacuum device in or connected to the robot RO to the fixation device 50. The first tube 52a and/or the second tube 53a may be flexible tubes made of a flexible material, such as rubber or an elastomer such as PTFE (PolyTetraFluoroEthylene).

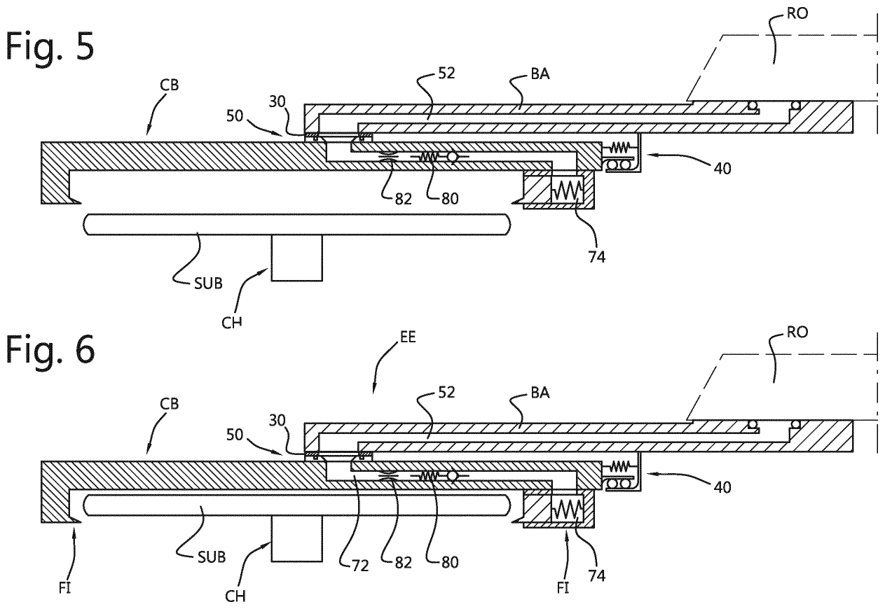

Exemplary steps of a method of operating the end-effector of the disclosure will be described herein below, with general reference to FIGS. 5 to 13.

FIG. 13 shows an example of pressure levels in the at least one vacuum line 52 during operation of the end-effector EE. In FIG. 13, pressure P in line 52 is indicated on the vertical axis, with values ranging from a reference level indicated as “0”, and a reduced pressure level or vacuum. FIG. 13 shows three respective pressure levels P₁, P₂ and P₃ as an example. In a practical embodiment, the reference level 0 may be about atmospheric pressure or 1 bar. Pressure levels P₁, P₂ and P₃ may be in range of about 0 to 200 kPa below the reference level. The reference level may be about 1 bar, or 1 atmosphere. Herein, P₁<P₂<P₃. For instance, P₃ may be about the reference level, or about the reference level minus 0 to 5 kPa. P₂ may be about 10 kPa to 50 kPa, for instance about 25 kPa, below the reference level. P₁ may be about 30 kPa to 100 kPa, for instance about 50 kPa, below the reference level.

Alternative options are possible, for instance using two or more separate pressure control lines 52a, 53a (FIG. 3C) or 52, 53 (FIG. 4). To create additional pressure control levels, additional check valves 82 may be added. In FIG. 13, time t is indicated on the horizontal axis. The two bars above the diagram indicate the position of the actuator 74 on the actuating finger 22 (first line) and the clamping body CB on the second line. Herein, the actuator 74 can move between the open position ACTₒₚ (wherein the substrate is released) and the closed position ACT_{cl} (wherein the actuator may engage a side or edge of the substrate). The clamping body can move between the fixed position CB_{fix} (wherein the clamping body is fixed with respect to the base) and the free position CB_{fr} (wherein the clamping body can move with respect to the base).

The Figures indicate steps of operating the end-effector to lift a substrate from a chuck and move the substrate to another location. However, similar steps allow the end-effector to move the substrate from another location to the chuck, or to any other location of choice.

In a first step, shown in FIG. 5, the robot RO moves the end-effector towards the substrate, positioning the clamping body above the substrate. The accuracy of positioning herein is determined by the best accuracy as achievable by the robot. The actuator 74 is in its open position, and the clamping body is in its fixed position.

In a second step, shown in FIG. 6, the robot lowers the base and the clamping body attached to it over the substrate. Ends of the respective fingers FI are levelled with the edge of the substrate SUB. Alternatively, or in addition, the chuck CH could raise the substrate SUB towards the clamping body CB.

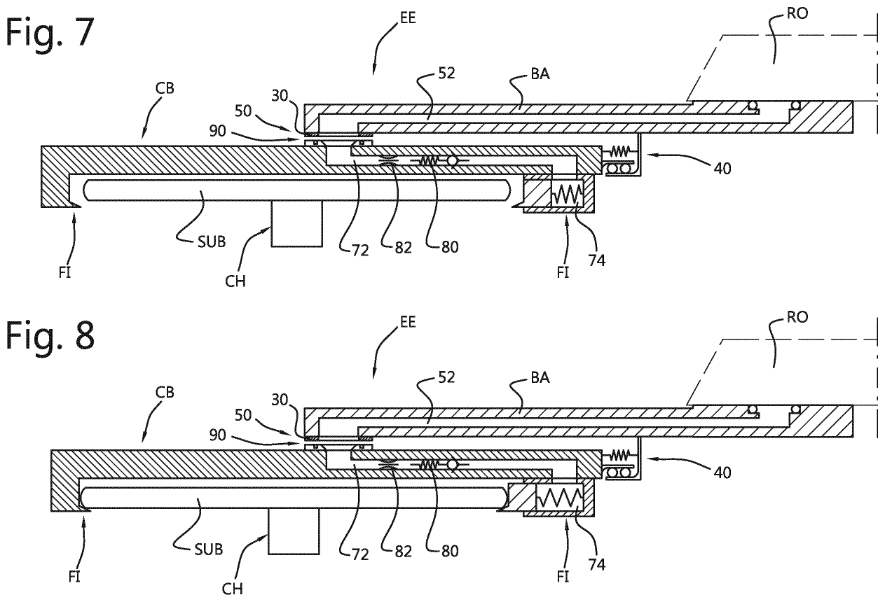

In a third step, shown in FIG. 7, the clamping body is switched into its free position. Herein, the clamping body is released from the base, potentially creating a space or opening 90 between the base and the clamping body. The guidance mechanism 40 herein guides and restricts freedom of movement of the clamping body CB with respect to the base BA. Releasing the clamping body can be achieved by, for instance, increasing the pressure in control line 52 up to pressure level P₃. P₃ may be at or near the reference level or atmospheric, as described above.

In a fourth step, indicated in FIG. 8, the actuator 74 switches to its closed position. Herein, the gripper part 78 of the actuator 74 engages a side or edge of the substrate, clamping the substrate between the gripper 78 and ends of the respective other fingers FI. Although shown in different figures, the third and fourth steps may be controlled or initiated by the same pressure, i.e. by the pressure P in line 52 rising to P₃. Due to a timing difference, for instance due to the flow restrictor 82 in line 72, the actuator 74 may in practice activate slightly later than the moment that the clamping body is released from the base. See FIG. 13, wherein the dotted line indicates a potential variation in the pressure level in the actuator with respect to the pressure level in line 52.

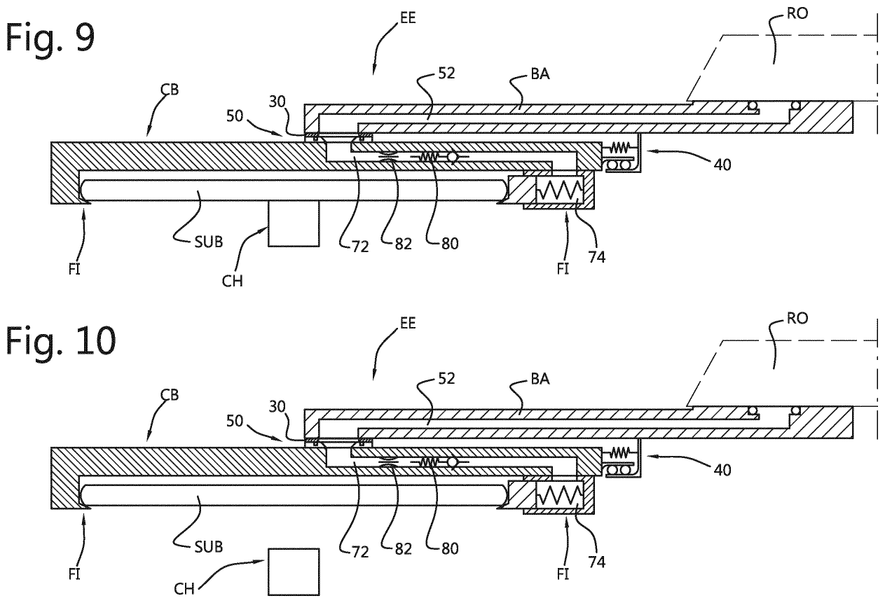

In a fifth step, see FIG. 9, the position of the clamping body CB is once again fixated with respect to the base. This step ensures that the substrate remains in the same position with respect to the chuck during transport to the other location. As explained above, maintaining the position of the substrate allows the lithographic process to maintain high throughput speeds even though substrates may be positioned slightly off with respect to a position of reference.

In a sixth step, see FIG. 10, the substrate is released from its location, for instance on the chuck CH. The robot RO lifts the base together with the clamping body CB and substrate.

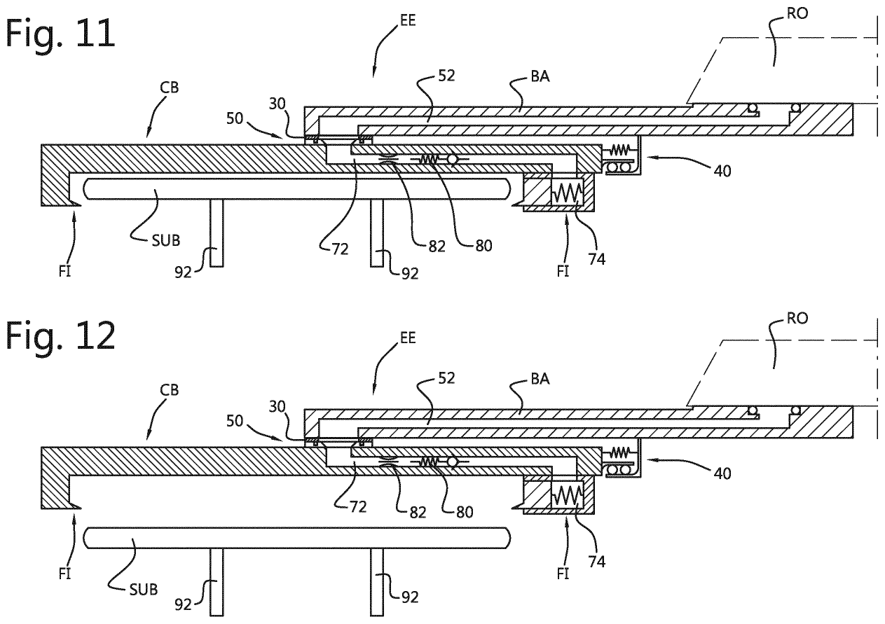

In a seventh step, see FIG. 11, the robot positions the substrate at the selected other location. The substrate is lowered. The actuator 74 is moved to its open position, disengaging the gripper 78 from the edge of the substrate.

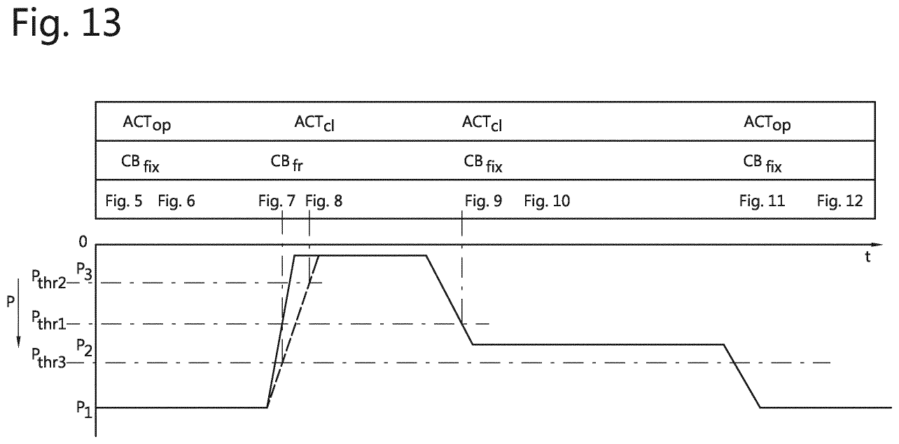

In an eighth step, see FIG. 12, the robot RO lifts the clamping body CB, leaving the substrate at the selected location 92.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below. Other aspects of the invention are set-out as in the following numbered clauses.

1. An end-effector for handling a substrate, comprising:
a base;
a clamping body comprising an actuator configured to switch between a first position, wherein the substrate is fixed in position with respect to the clamping body, and a second position, wherein the substrate is released;
a guidance mechanism connecting the clamping body to the base while allowing freedom of movement of the clamping body relative to the base within a predetermined range of motion; and
a fixation mechanism for switching a connection between the clamping body and the base between a fixed position, wherein the clamping body is fixated relative to the base, and a free position, wherein the clamping body can move relative to the base.
   2. The end-effector of clause 1, wherein the clamping body comprises at least one fixed finger and at least one actuating finger being provided with the actuator, wherein in the first position the substrate is fixed in position between ends of the at least one fixed finger and the actuator of the at least one actuating finger.
   3. The end-effector of clause 1 or 2, wherein the guidance mechanism comprises at least one spring element, each spring element having one end connected to the base and an opposite end connected to the clamping body.
   4. The end-effector of clause 3, wherein the at least one spring element comprises a leaf spring, or a bent piece of flexible material, such as spring steel or a similar material.
   5. The end-effector of clauses 3 or 4, wherein the ends of the at least one spring element are connected to the base and to the clamping body by one or more of an adhesive, welding, or soldering.
   6. The end-effector of clauses 3 to 5, wherein the at least one spring element has a shape allowing relative motion of its opposite ends in the horizontal plane (x, y) while preventing or at least limiting movement in the vertical direction (z).
   7. The end-effector of any of the previous clauses, wherein the predetermined range of motion allowed by the guidance mechanism includes lateral movement in the horizontal plane of +/−5 mm, for instance about +/−4 mm, for instance about +/−3 mm, for instance about 2.5 mm, for instance about +/−2 mm, for instance about +/−1.5 mm, for instance about +/−1 mm, for instance about +/−500 μm, for instance about +/−250 μm, for instance about +/−200 μm, for instance about +/−150 μm, for instance about +/−100 μm, for instance about +/−50 μm, for instance about +/−20 μm, for instance about +/−10 μm.
   8. The end-effector of any of the previous clauses, wherein the predetermined range of motion allowed by the guidance mechanism includes rotation θ, wherein θ is in a range of +/−5 degrees, for instance +/−4 degrees, for instance +/−3 degrees, for instance +/−2 degrees, for instance +/−1 degree, for instance +/−0.5 degrees, for instance +/−0.4 degrees, for instance +/−0.3 degrees, for instance +/−0.2 degrees, for instance +/−0.1 degree.
   9. The end effector of any of the previous clauses, wherein the guidance mechanism is adapted to move the clamping body to a reference position with respect to the base when the fixation mechanism is in the free position.
   10. The end-effector of any of the previous clauses, wherein the fixation mechanism is connected to at least one vacuum line to control the fixation mechanism.
   11. The end-effector of clause 10, wherein the at least one vacuum line comprises a first section included in the base, the first section being connected to a vacuum bridge having one or more openings connecting the first section in the base to a corresponding vacuum line section in the clamping body, the vacuum line section in the clamping body being connected to the actuator.
   12. The end-effector of clause 11, the vacuum line section in the clamping body being provided with a check valve and/or a flow restrictor.
   13. The end-effector of one of the previous clauses, the actuator comprising a spring for pre-tensioning a gripper, the spring pushing the gripper outward in a position allowing engagement with an edge of the substrate.
   14. A lithographic apparatus comprising the end-effector according to one of clauses 1 to 13.
   15. A method of using an end-effector for handling a substrate,
the end-effector comprising:
a base;
a clamping body comprising an actuator configured to switch between a first position, wherein the substrate is fixed in position with respect to the clamping body, and a second position, wherein the substrate is released;
a guidance mechanism connecting the clamping body to the base while allowing freedom of movement of the clamping body relative to the base within a predetermined range of motion; and
a fixation mechanism for switching a connection between the clamping body and the base between a fixed position, wherein the clamping body is fixated relative to the base, and a free position, wherein the clamping body can move relative to the base,
the method comprising the steps of:
moving the clamping body in lateral direction covering a substrate;
lowering the clamping body onto the substrate;
switching the fixation mechanism to the free position;
switching the actuator to the first position;
switching the fixation mechanism to the fixed position;
lifting the clamping body and the substrate and moving the clamping body to another location;
switching the actuator to the second position;
lifting the clamping body without the substrate.
   16. The method of clause 15, wherein the step of switching the fixation mechanism to the fixed position includes decreasing a pressure in a first vacuum line below a first threshold Pₜₕᵣ₁.
   17. The method of clause 15 or 16, wherein the step of switching the fixation mechanism to the free position includes increasing a pressure in the first vacuum line to exceed a second threshold Pₜₕᵣ₂.
   18. The method of one of clauses 15 to 17, wherein the step of switching the actuator to the second position includes decreasing a pressure in a second vacuum line to below a third threshold Pₜₕᵣ₃ and/or wherein the step of switching the actuator to the first position includes increasing a pressure in the second vacuum line to exceed a fourth threshold Pₜₕᵣ₄.
   19. The method of one of clauses 15 to 18, comprising the step of projecting a patterned beam of radiation onto the substrate.

1-19. (canceled)

20. An end-effector comprising:
a base;
a clamping body comprising an actuator configured to switch between a first position, wherein a substrate is fixed in position with respect to the clamping body, and a second position, wherein the substrate is released;
a guidance mechanism connecting the clamping body to the base while allowing freedom of movement of the clamping body relative to the base within a predetermined range of motion; and
a fixation mechanism configured for switching a connection between the clamping body and the base between a fixed position, wherein the clamping body is fixated relative to the base, and a free position, wherein the clamping body can move relative to the base.

21. The end-effector of claim 20, wherein:
the clamping body comprises at least one fixed finger and at least one actuating finger being provided with the actuator, wherein in the first position the substrate is fixed in position between ends of the at least one fixed finger and the actuator of the at least one actuating finger.

22. The end-effector of claim 20, wherein the guidance mechanism comprises at least one spring element, each spring element having a first end connected to the base and a second, opposite end connected to the clamping body.

23. The end-effector of claim 22, wherein the at least one spring element comprises a leaf spring, a bent piece of flexible material, spring steel, or a similar material.

24. The end-effector of claim 22, wherein the first and second ends of the at least one spring element are connected to the base and to the clamping body by one or more of an adhesive, welding, or soldering.

25. The end-effector of claim 22, wherein the at least one spring element has a shape allowing relative motion of its opposite ends in a horizontal plane (x, y) while preventing or at least limiting movement in a vertical direction (z).

26. The end-effector of claim 20, wherein the predetermined range of motion allowed by the guidance mechanism comprises lateral movement in a horizontal plane of about +/−5 mm, about +/−4 mm, about +/−3 mm, about 2.5 mm, about +/−2 mm, about +/−1.5 mm, about +/−1 mm, about +/−500 μm, about +/−250 μm, about +/−200 μm, about +/−150 μm, about +/−100 μm, about +/−50 μm, about +/−20 μm, or about +/−10 μm.

27. The end-effector of claim 20, wherein the predetermined range of motion allowed by the guidance mechanism includes rotation θ, wherein θ is in a range of about +/−5 degrees, about +/−4 degrees, about +/−3 degrees, about +/−2 degrees, about +/−1 degree, about +/−0.5 degrees, about +/−0.4 degrees, about +/−0.3 degrees, about +/−0.2 degrees, or about +/−0.1 degree.

28. The end effector of claim 20, wherein the guidance mechanism is adapted to move the clamping body to a reference position with respect to the base in response to the fixation mechanism being in the free position.

29. The end-effector of claim 20, wherein the fixation mechanism is connected to at least one vacuum line to control the fixation mechanism.

30. The end-effector of claim 29, wherein the at least one vacuum line comprises:
a first section included in the base, the first section being connected to a vacuum bridge having one or more openings connecting the first section in the base to a corresponding vacuum line section in the clamping body, the vacuum line section in the clamping body being connected to the actuator.

31. The end-effector of claim 30, the vacuum line section in the clamping body being provided with a check valve and/or a flow restrictor.

32. The end-effector of claim 20, the actuator comprising a spring for pre-tensioning a gripper, the spring pushing the gripper outward in a position allowing engagement with an edge of the substrate.

33. A lithographic apparatus comprising the end-effector of claim 20.

34. A method comprising:
using an end-effector comprising:
a base;
a clamping body comprising an actuator configured to switch between a first position, wherein a substrate is fixed in position with respect to the clamping body, and a second position, wherein the substrate is released;
a guidance mechanism connecting the clamping body to the base while allowing freedom of movement of the clamping body relative to the base within a predetermined range of motion; and
a fixation mechanism for switching a connection between the clamping body and the base between a fixed position, wherein the clamping body is fixated relative to the base, and a free position, wherein the clamping body can move relative to the base,
moving the clamping body in lateral direction covering a substrate;
lowering the clamping body onto the substrate;
switching the fixation mechanism to the free position;
switching the actuator to the first position;
switching the fixation mechanism to the fixed position;
lifting the clamping body and the substrate and moving the clamping body to another location;
switching the actuator to the second position; and
lifting the clamping body without the substrate.

35. The method of claim 34, wherein the switching the fixation mechanism to the fixed position comprises decreasing a pressure in a first vacuum line below a first threshold Pₜₕᵣ₁.

36. The method of claim 34, wherein the switching the fixation mechanism to the free position comprises increasing a pressure in the first vacuum line to exceed a second threshold Pₜₕᵣ₂.

37. The method of one of claims 34, wherein:
the switching the actuator to the second position comprises decreasing a pressure in a second vacuum line to below a third threshold Pₜₕᵣ₃ and/or
the switching the actuator to the first position includes increasing a pressure in the second vacuum line to exceed a fourth threshold Pₜₕᵣ₄.

38. The method of claim 34, comprising the projecting a patterned beam of radiation onto the substrate.
